(19) United States
(12) Patent Application Publication
(10) Pub. No.: US 2023/0202143 A1
(43) Pub. Date: Jun. 29, 2023

(54) ORGANIC CONDUCTIVE FILM PRODUCTION METHOD, ORGANIC CONDUCTIVE FILM, AND LAMINATE

(71) Applicant: TOPPAN INC., Tokyo (JP)

(72) Inventors: Hiroyoshi NISHIYAMA, Tokyo (JP); Ryo SHODA, Tokyo (JP)

(73) Assignee: TOPPAN INC., Tokyo (JP)

(21) Appl. No.: 18/118,369

(22) Filed: Mar. 7, 2023

Related U.S. Application Data
(63) Continuation of application No. PCT/JP2021/031891, filed on Aug. 31, 2021.

(30) Foreign Application Priority Data
Sep. 8, 2020 (JP) 2020-150394

(51) Int. Cl. B32B 17/06; B32B 27/06; C09D 165/00

(52) U.S. Cl. CPC B32B 17/06; B32B 27/06; C09D 165/00; B32B 2255/26; B32B 2255/10; B32B 27/36

(57) ABSTRACT

A method for producing an organic conductive film includes a step of preparing a coating liquid containing an acid-based organic conductive polymer, an alkali neutralizing agent, and a liquid medium, and having a pH of 4.0 to 6.5 at 25° C., a step of applying the coating liquid to a base layer, and a step of removing the liquid medium from the applied coating liquid.

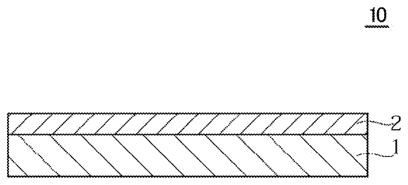

### CROSS-REFERENCE TO RELATED PATENT APPLICATIONS

This application is a continuation application filed under 35 U.S.C. § 111(a) claiming the benefit under 35 U.S.C. §§ 120 and 365(c) of International Patent Application No. PCT/JP2021/031891, filed on Aug. 31, 2021, which in turn claims the benefit of JP 2020-150394, filed Sep. 8, 2020, the disclosures of all which are incorporated herein by reference in its entirety.

### TECHNICAL FIELD

The present disclosure relates to organic conductive film production methods, organic conductive films, and laminates.

### BACKGROUND ART

In recent years, liquid crystal displays, electroluminescent displays, solar cells, touch panels, and the like are being widely used. These devices include, for example, an indium tin oxide (ITO) laminated as a transparent electrode on a film. Unfortunately, for indium as a material of ITO, there are concerns over global resource depletion and safety, and accordingly, alternative organic materials are being studied. An example of such organic materials is a 71-conjugated conductive polymer, and a specific example of the 71-conjugated conductive polymer is a polythiophene-based conductive polymer.

Regarding the technique of forming a π-conjugated conductive polymer film, the use of a conductive polymer solution containing a π-conjugated conductive polymer is known (see, for example, PTL 1).

[Citation List] [Patent Literature] PTL 1: JP H07-105718 A

### SUMMARY OF THE INVENTION

### Technical Problem

When a solution is prepared according to PTL 1 and contains an acid-based organic conductive polymer, this solution may be highly acidic due to its composition. In that case, from the viewpoint of ensuring safety, retarding corrosion of a processing apparatus, and the like, the pH of the solution may be adjusted to be a neutral or nearly neutral value using a neutralizing agent or the like. Unfortunately, the inventors have found that a conductive polymer layer formed using a solution with a pH thus adjusted has insufficient light resistance.

The present disclosure has been made in view of the above circumstances; an object thereof is to provide methods for producing highly light-resistant organic conductive films. Another object of the present disclosure is to provide highly light-resistant organic conductive films.

### Solution to Problem

An intensive study conducted by the inventors revealed that light resistance is affected by the amount of a component derived from an alkali neutralizing agent and remaining in a conductive layer formed from a solution containing an acid-based organic conductive polymer. Based on this finding, the inventors have completed the present invention.

A method according to an aspect of the present disclosure for producing an organic conductive film includes a step of preparing a coating liquid containing an acid-based organic conductive polymer, an alkali neutralizing agent, and a liquid medium, and having a pH of 4.0 to 6.5 at 25° C., a step of applying the coating liquid to a base layer, and a step of removing the liquid medium from the applied coating liquid. Using a coating liquid with a pH thus adjusted allows appropriate control of the quantity of cations contained in an acid-based organic conductive polymer layer and derived from an alkali neutralizing agent, as will be described later, thus enabling production of a highly light-resistant organic conductive film. The study conducted by the inventors thus revealed that it is important for the coating liquid not to have an exceedingly high or low pH, that is, for the acid-based organic conductive polymer layer not to have an exceedingly high or low density of cations derived from an alkali neutralizing agent.

According to an aspect of the production method, the acid-based organic conductive polymer may include a polythiophene-based conductive polymer.

According to an aspect of the production method, the alkali neutralizing agent may include ammonia water.

An organic conductive film according to an aspect of the present disclosure includes a base layer and an acid-based organic conductive polymer layer disposed on the base layer, the acid-based organic conductive polymer layer containing cations derived from an alkali neutralizing agent, wherein the cations contained in the acid-based organic conductive polymer layer have a density of 0.5 to 5.0 mg/cm³. Designing the acid-based organic conductive polymer layer to contain cations derived from an alkali neutralizing agent at a density of 0.5 to 5.0 mg/cm³ allows the organic conductive film to have high light resistance.

According to an aspect of the organic conductive film, the acid-based organic conductive polymer may include a polythiophene-based conductive polymer.

According to an aspect of the organic conductive film, the cations derived from the alkali neutralizing agent may include ammonium ions.

According to an aspect of the organic conductive film, the base layer may include a resin substrate or a glass substrate.

According to an aspect, any of the above organic conductive films may be used as a resistive coating of an electromagnetic wave suppression sheet or as a circuit material in an electronic device.

### Advantageous Effects of Invention

The present disclosure provides methods for producing highly light-resistant organic conductive films. The present disclosure also provides highly light-resistant organic conductive films. Such organic conductive films can be obtained using the above production methods.

### BRIEF DESCRIPTION OF THE DRAWINGS

The FIGURE is a schematic cross-sectional view of an organic conductive film according to an embodiment.

### DETAILED DESCRIPTION

Embodiments of the present invention will be described below with reference to the drawings. In the following description of the drawings to be referred, components or functions identical with or similar to each other are given the same or similar reference signs, unless there is a reason not to. It should be noted that the drawings are only schematically illustrated, and thus the relationship between thickness and two-dimensional size of the components, and the thickness ratio between the layers, are not to scale. Therefore, specific thicknesses and dimensions should be understood in view of the following description. As a matter of course, dimensional relationships or ratios may be different between the drawings.

Further, the embodiments described below are merely examples of configurations for embodying the technical idea of the present invention. The technical idea of the present invention does not limit the materials, shapes, structures, arrangements, and the like of the components to those described below. The technical idea of the present invention can be modified variously within the technical scope defined by the claims. The present invention is not limited to the following embodiments within the scope not departing from the spirit of the present invention. For the sake of clarity, the drawings may be illustrated in an exaggerated manner as appropriate.

In any group of successive numerical value ranges described in the present specification, the upper limit value or lower limit value of one numerical value range may be replaced with the upper limit value or lower limit value of another numerical value range. In the numerical value ranges described in the present specification, the upper limit values or lower limit values of the numerical value ranges may be replaced with values shown in examples. The configuration according to a certain embodiment may be applied to other embodiments.

The embodiments of the present invention are a group of embodiments based on a single unique invention. The aspects of the present invention are those of the group of embodiments based on a single invention. Configurations of the present invention can have aspects of the present disclosure. Features of the present invention can be combined to form the configurations. Therefore, the features of the present invention, the configurations of the present invention, the aspects of the present disclosure, and the embodiments of the present invention can be combined, and the combinations can have a synergistic function and exhibit a synergistic effect.

<Organic Conductive Film>

The FIGURE is a schematic cross-sectional view of an organic conductive film according to an embodiment. An organic conductive film 10 includes a base layer 1, and an acid-based organic conductive polymer layer 2 disposed on the base layer 1.

[Base Layer]

The base layer functions as a substrate of the organic conductive film. Examples of materials of the base layer include resin and glass. That is, the base layer may include a resin substrate or a glass substrate, or may be a resin substrate or a glass substrate.

Examples of the resin include, but are not limited to, polyester resins such as polyethylene terephthalate (PET), polybutylene terephthalate (PBT), polyethylene naphthalate, and modified polyester; polyolefin resins such as polyethylene (PE) resin, polypropylene (PP) resin, and cyclic olefin resin; vinyl-based resins such as polyvinyl chloride and polyvinylidene chloride; polyvinyl acetal resins such as polyvinyl butyral (PVB); polyether ether ketone (PEEK) resins; polysulfone (PSF) resins; polyether sulfone (PES) resins; polycarbonate (PC) resins; polyamide resins; polyimide resins; polystyrene resins; acrylic resins; and cellulose triacetate (TAC) resins. Considering availability, cost, and the like, the resin may be a polyester resin such as PET or PBT, or a polyolefin resin such as PP.

Examples of the glass include, but are not limited to, soda-lime glass, lead glass, borosilicate glass, and quartz glass. Considering availability, cost, and the like, the glass may be soda-lime glass.

The base layer may include one or more layers composed of these materials. When the base layer is formed of a plurality of layers (i.e., a laminate), a combination of resin substrates or a combination of resin and glass substrates may be used. Examples of a combination of resin substrates include a PP layer/PET layer and PP layer/PBT layer.

Although the thickness of the base layer is not particularly limited, it may be, for example, 10 to 200 μm, and preferably 25 to 75 μm, in view of transparency and strength according to its use. Further, considering the coating performance of a coating liquid, the adhesion to the polymer layer, and the like, the surface of the base layer may be subjected to corona treatment or adhesion enhancement treatment if necessary.

The base layer may or may not transmit electromagnetic waves at wavelengths in the visible region, depending on the specifications of the organic conductive film. For example, if the organic conductive film is required to transmit electromagnetic waves at wavelengths in the visible region, a base layer may be selected that transmits the electromagnetic waves therethrough. Further, if the substrate is required to have a pattern or a wood-grain design, printing may be performed on the base layer, or undulations may be formed on the surface of the base layer.

[Acid-Based Organic Conductive Polymer Layer]

The acid-based organic conductive polymer layer is electrically conductive and contains an acid-based organic conductive polymer. As used herein, “acid-based organic conductive polymer” refers to a conductive complex containing a π-conjugated conductive polymer and a polyanion dopant for the π-conjugated conductive polymer. Examples of the π-conjugated conductive polymer include, but are not limited to, polythiophene, polypyrrole, polyaniline, polyacethylene, polyphenylene vinylene, polynaphthalene, and derivatives thereof. Among them, in view of transparency, electrical conductivity, stability, and the like, the π-conjugated conductive polymer may be a polythiophene-based conductive polymer in particular.

Examples of the polythiophene-based conductive polymer include polythiophene, poly(3-methylthiophene), poly(3-ethylthiophene), poly(3-propylthiophene), poly(3-butylthiophene), poly(3-hexylthiophene), poly(3-heptylthiophene), poly(3-octylthiophene), poly(3-decylthiophene), poly(3-dodecylthiophene), poly(3-octadecylthiophene), poly(3-bromothiophene), poly(3-chlorothiophene), poly(3-iodothiophene), poly(3-cyanothiophene), poly(3-phenylthiophene), poly(3,4-dimethylthiophene), poly(3,4-dibutylthiophene), poly(3-hydroxythiophene), poly(3-methoxythiophene), poly(3-ethoxythiophene), poly(3-butoxythiophene), poly(3-hexyloxythiophene), poly(3-heptyloxythiophene), poly(3-octyloxythiophene), poly(3-decyloxythiophene), poly(3-dodecyloxythiophene), poly(3-octadecyloxythiophene), poly(3,4-dihydroxythiophene), poly(3,4-dimethoxythiophene), poly(3,4-diethoxythiophene), poly(3,4-dipropoxythiophene), poly(3,4-dibutoxythiophene), poly(3,4-dihexyloxythiophene), poly(3,4-diheptyloxythiophene), poly(3,4-dioctyloxythiophene), poly(3,4-didecyloxythiophene), poly(3,4-didodecyloxythiophene), poly(3,4-ethylenedioxythiophene), poly(3,4-propylenedioxythiophene), poly(3,4-butylenedioxythiophene), poly(3-methyl-4-methoxythiophene), poly(3-methyl-4-ethoxythiophene), poly(3-carboxythiophen), poly(3-methyl-4-carboxythiophen), poly(3-methyl-4-carboxyethylthiophen), and poly(3-methyl-4-carboxybutylthiophen). The polythiophene-based conductive polymer may be poly(3,4-ethylenedioxythiophene) in view of electrical conductivity, chemical stability, productivity, and the like.

The polythiophene-based conductive polymers may be used singly or in combination.

The acid-based organic conductive polymer layer contains a polyanion dopant for a π-conjugated conductive polymer. This improves the electrical conductivity of the acid-based organic conductive polymer layer. Examples of the polyanion dopant include polymer acids having a sulfo group, such as alkanesulfonic acids, polystyrene sulfonic acids, polyvinyl sulfuric acids, polyvinylsulfonic acids, polyarylsulfonic acids, polyacrylsulfonic acids, polymethacrylsulfonic acids, poly(2-acrylamido-2-methylpropanesulfonic acids), polyisoprenesulfonic acids, polysulphoethyl methacrylate, poly(4-sulfobutyl methacrylate), and polymethacryloxybenzenesulfonic acids; and organic acids having a sulfo group, such as p-toluenesulfonic acids and dodecylbenzenesulfonic acids. The polyanion dopant may be a polystyrene sulfonic acid in terms of chemical stability and electrical conductivity.

The polyanion dopants can be used singly or in combination.

At least part of the polythiophene-based conductive polymer and at least part of the polyanion dopant form a conductive complex in a layer. In view of transparency, electrical conductivity, and the like, the conductive complex may be poly(3,4-ethylenedioxythiophene)-poly(styrenesulfonate)(PEDOT-PSS), which is a complex made of poly(3,4-ethylenedioxythiophene)(PEDOT) and polystyrene sulfonate (PSS).

The acid-based organic conductive polymer layer may further contain another component (e.g., binder or the like) other than the polythiophene-based conductive polymer and the polyanion dopant, unless desired effects are significantly impaired. In that case, the total amount of the polythiophene-based conductive polymer and polyanion dopant in the acid-based organic conductive polymer layer is 50 mass % or more, preferably 80 mass % or more, and more preferably 90 mass % or more.

The thickness of the acid-based organic conductive polymer layer is not particularly limited, but may be, for example, 10 nm to 1 m, and preferably 200 to 600 nm.

As will be described later, the acid-based organic conductive polymer layer may be formed by applying, to the base layer, a coating liquid containing an acid-based organic conductive polymer and an alkali neutralizing agent and having a pH of 4.0 to 6.5 at 25° C. From the viewpoint of maintaining high light resistance, the cations contained in the acid-based organic conductive polymer layer and derived from the alkali neutralizing agent has a density of 0.5 to 5.0 mg/cm³, but may be preferably 3.0 to 5.0 mg/cm³, and more preferably 4.5 to 5.0 mg/cm³. The cations are contained in the acid-based organic conductive polymer layer at a density greater than or equal to a certain amount, presumably because cations are trapped due to hydrogen bonding or the like between the cations and the acid-based organic conductive polymer, and the trapped cations remain in the layer after removal of the liquid medium.

The cation content may be measured by ion chromatography. Specifically, the organic conductive film is put into an extractant (ultrapure water) and allowed to stand for 24 hours at 25° C. The extractant after standing is diluted with ultrapure water by a factor of 50, and then cations are quantified by ion chromatography. Based on the quantification results, the quantity of cations remaining in the acid-based organic conductive polymer layer can be calculated.

The cations derived from an alkali neutralizing agent may include ammonium ions. In that case, the quantity of ammonium ions present in the acid-based organic conductive polymer layer, as measured by ion chromatography, is 0.5 to 5.0 mg/cm³, preferably 3.0 to 5.0 mg/cm³, and more preferably 4.5 to 5.0 mg/cm³.

The acid-based organic conductive polymer layer has high light resistance, which means that the surface resistivity thereof will not easily increase over time. The surface resistivity variation in the acid-based organic conductive polymer layer, as measured by four-terminal sensing and represented by the following expression, may be 4.0×10² or less, and more preferably 3.0×10² or less.

Surface resistivity variation=surface resistivity after light resistance test/surface resistivity before light resistance test

Note that the light resistance test is a xenon-type accelerated light resistance test (conditions: irradiance of 60 W/m², BPT temperature of 63° C., chamber temperature of 40° C., chamber humidity of 50% RH, and test time of 500 hours).

The above organic conductive film may be used as, but is not limited to, a resistive coating of an electromagnetic wave suppression sheet, or a circuit material in an electronic device Note that the organic conductive film is used as with a resistive coating layer described in JP 6523563 B2, serving as an electromagnetic wave suppression sheet. Further, the organic conductive film is used as with a hole-transport layer described in JP 2005-71929 A, serving as an electronic device.

<Electromagnetic Wave Suppression Sheet>

The electromagnetic wave suppression sheet can be a laminate including the organic conductive film, a dielectric layer, and an electromagnetic shielding layer. Examples of methods for producing the electromagnetic wave suppression sheet include, but are not limited to, the following methods:

(1) A method of bonding the organic conductive film to a laminate of a dielectric layer and an electromagnetic shielding layer.

(2) A method of coating a laminate of a dielectric layer and an electromagnetic shielding layer with an acid-based organic conductive polymer layer, and bonding a base layer to the acid-based organic conductive polymer layer.

(3) A method of coating a laminate of a dielectric layer and an electromagnetic shielding layer with an acid-based organic conductive polymer layer, and extruding a base layer onto the acid-based organic conductive polymer layer.

An electromagnetic wave suppression sheet according to an aspect includes a resistive coating, a dielectric layer, and an electromagnetic shielding layer; each of these layers is optically transmissive; and the resistive coating includes an acid-based organic conductive polymer layer. Note that, in another embodiment of the electromagnetic wave suppression sheet, a base layer of the resistive coating may be designed to fully or partly block electromagnetic waves at wavelengths in the visible region.

In an embodiment of the electromagnetic wave suppression sheet, the dielectric layer has a predetermined thickness that allows absorption of electromagnetic waves in a high frequency band of frequencies higher than or equal to those of the millimeter wave band (30 GHz to 300 GHz); the electromagnetic shielding layer is configured as a conductive mesh having an aperture ratio of 35% or more and 85% or less; the total luminous transmittance thereof is 30% or more; and the amount of attenuation of electromagnetic waves in the electromagnetic wave suppression sheet is 20 dB or more.

According to an embodiment of the electromagnetic wave suppression sheet, the electromagnetic shielding layer has a surface resistivity of 0.3 Ω/sq or less.

According to an embodiment of the electromagnetic wave suppression sheet, the resistive coating has a surface resistivity of −15% to +20% relative to vacuum impedance.

<Method for Producing Organic Conductive Film>

A method for producing an organic conductive film includes a step of preparing a coating liquid containing an acid-based organic conductive polymer, an alkali neutralizing agent, and a liquid medium, a step of applying the coating liquid to a base layer, and a step of removing the liquid medium from the applied coating liquid.

[Alkali Neutralizing Agent]

The coating liquid contains an alkali neutralizing agent in addition to the above materials exemplified in relation to the acid-based organic conductive polymer layer. The alkali neutralizing agent is not particularly limited, as long as it can adjust the pH of the coating liquid and does not affect a compound state of the acid-based organic conductive polymer. Examples of the alkali neutralizing agent include hydroxides or carbonates of alkali metals, alkaline-earth metals, or the like; ammonium compounds of ammonia; and amines. Considering availability, the alkali neutralizing agent may include ammonia.

[Liquid Medium]

The liquid medium is not particularly limited; examples thereof include water, organic solvents, solvent mixtures of water and organic solvent, and the like.

The coating liquid has a pH of 4.0 to 6.5 at 25° C. Adjusting the pH thereof to be within this range allows the acid-based organic conductive polymer layer formed to have high light resistance. From this viewpoint, the pH of the coating liquid may be 4.5 to 5.5.

Examples of methods of applying the coating liquid to the base layer include, but are not limited to, known coating techniques, such as gravure coating, reverse roll coating, die coating, air doctor coating, blade coating, rod coating, bar coating, curtain coating, knife coating, transfer roll coating, squeeze coating, impregnation coating, kiss coating, spray coating, calender coating, and extrusion coating.

Examples of methods of removing the liquid medium include heating, decompression, and combinations thereof. If, for example, the liquid medium is removed by heating, the heating temperature may be 50 to 200° C., and more preferably 90 to 150° C. Depending on the heating temperature, the heating time may be, for example, 30 seconds to 15 minutes, and more preferably 1 to 5 minutes.

### Examples

The present invention will be described in greater detail by way of the following examples, but the present invention is not limited to these examples.

[Preparation of Coating Liquids]

As an aqueous poly(3,4-ethylenedioxythiophene)-poly(styrenesulfonate)(PEDOT-PSS) dispersion, an aqueous dispersion Clevios PH 1000 (pH=3) available from Heraeus was prepared. Additionally, as a solution containing an alkali neutralizing agent, ammonia water (pH=12) available from Kanto Chemical Co., Inc. was prepared. Then, coating liquids 1 to 3 were prepared according to Table 1. Coating liquid 1 was the above aqueous dispersion itself, and coating liquid 2 and coating liquid 3 were each prepared by adding ammonia water to the aqueous dispersion PH 1000 to adjust the pH thereof. The pH of the coating liquids at 25° C. was measured with a benchtop pH meter F-37 available from Horiba, Ltd.

TABLE 1

| Coating liquid | pH (25° C.) |
|---|---|
| 1 | <3 |
| 2 | 5 |
| 3 | 7 |

<Production of Organic Conductive Film>

Each of the above coating liquids was applied with a bar coater #18 to a polyethylene terephthalate substrate (PET; 50 m in thickness) to form a coating film thereon. The obtained coating films were heated at 120° C. for 1 minute to form a PEDOT-PSS layer (about 300 nm in thickness) on the respective PET substrates. Thus, organic conductive films were produced.

<Evaluation of Organic Conductive Films>

[Cation Content in PEDOT-PSS Layer]

The ammonium ions remaining in the PEDOT-PSS layers were quantified using an ion chromatography system DX-320 available from Dionex Corporation. Each of the organic conductive films (sample size: 1 cm² (1 cm×1 cm)) was put into an extractant (100 ml of ultrapure water) and allowed to stand for 24 hours at 25° C. Each extractant after standing was diluted with ultrapure water by a factor of 50, and then the ammonium ions therein were quantified by ion chromatography. Based on the quantification results, the quantity of ammonium ions remaining in the PEDOT-PSS layers was calculated. The results are shown in Table 2.

[Surface Resistivity Variation]

The surface resistivity of the PEDOT-PSS layers before and after the light resistance test was measured at 25° C. with a Loresta-GP (MCP-T610; in-line four point probe (ASP) system) available from Mitsubishi Chemical Analytech Co., Ltd.). Three samples of each organic conductive film (sample size: 25 cm² (5 cm×5 cm)) were prepared, and the surface resistivity was measured for each sample five times. The average of the surface resistivities was taken for each set of the three samples of the organic conductive films, and each average was taken as the surface resistivity of the corresponding PEDOT-PSS layer. Then, the surface resistivity variations were calculated using the expression below. The results are shown in Table 2.

Surface resistivity variation=surface resistivity after light resistance test/surface resistivity before light resistance test

(Note that the light resistance test was performed using Xenon Weather Meter X75 available from Suga Test Instruments Co., Ltd. under the following conditions: irradiance of 60 W/m², BPT temperature of 63° C., chamber temperature of 40° C., chamber humidity of 50% RH, and test time of 500 hours.)

TABLE 2

| | | | Surface resistivity variation | | |
|---|---|---|---|---|---|
| | Coating | Cation content | After | After | After |
| | liquid | (Unit: mg/cm³) | 100 hr. | 250 hr. | 500 hr. |
| Comp. Ex. 1 | 1 | 0 | 1.8 | 5.9 | 431.2 |
| Example 1 | 2 | 4.8 | 1.9 | 5.7 | 293.7 |
| Comp. Ex. 2 | 3 | 5.5 | 2.1 | 9.6 | 4608.3 |

The surface resistivity variation observed after the elapse of 500 hours was an order of magnitude larger in Comparative Example 2 than in Example 1.

In contrast, the surface resistivity variation in Example 1 was low even after 500 hours had elapsed; specifically, the variation in the surface resistivity was confined within a factor of 300. This value was smaller than that of Comparative Example 1.

[Reference Signs List] 1 . . . Base layer; 2 . . . Acid-based organic conductive polymer layer; 10 . . . Organic conductive film.

What is claimed is:

1. A method for producing an organic conductive film, comprising the steps of:
a step of preparing a coating liquid containing an acid-based organic conductive polymer, an alkali neutralizing agent, and a liquid medium, and having a pH of 4.0 to 6.5 at 25° C.;
a step of applying the coating liquid to a base layer; and
a step of removing the liquid medium from the applied coating liquid.

2. The production method of claim 1, wherein:
the acid-based organic conductive polymer includes a polythiophene-based conductive polymer.

3. The production method of claim 1, wherein:
the alkali neutralizing agent includes ammonia.

4. An organic conductive film, comprising:
a base layer; and
an acid-based organic conductive polymer layer disposed on the base layer, the acid-based organic conductive polymer layer containing cations derived from an alkali neutralizing agent,
wherein:
the cations contained in the acid-based organic conductive polymer layer have a density of 0.5 to 5.0 mg/cm³.

5. The film of claim 4, wherein:
the acid-based organic conductive polymer includes a polythiophene-based conductive polymer.

6. The film of claim 4, wherein:
the cations derived from the alkali neutralizing agent include ammonium ions.

7. The film of claim 4, wherein:
the base layer includes a resin substrate or a glass substrate.

8. The film of claim 4, for use as a resistive coating of an electromagnetic wave suppression sheet or as a circuit material in an electronic device.

9. A laminate, comprising:
a film of claim 4;
a dielectric layer; and
an electromagnetic shielding layer.
